(19) United States
(12) Patent Application Publication
(10) Pub. No.: US 2018/0328965 A1
(43) Pub. Date: Nov. 15, 2018

(54) INDUCTIVE VOLTAGE TESTER AND METHOD OF USING THE SAME

(71) Applicant: SHENZHEN EVERBEST MACHINERY INDUSTRY CO., LTD., Shenzen (CN)

(72) Inventor: Jianmin Yuan, Shenzen (CN)

(73) Assignee: SHENZHEN EVERBEST MACHINERY INDUSTRY CO., LTD., Shenzen (CN)

(21) Appl. No.: 15/550,236

(22) PCT Filed: Feb. 6, 2016
(86) PCT No.: PCT/CN2016/073729

§ 371 Date: Aug. 10, 2017

(51) Int. Cl. G01R 15/18; G01R 19/155

(52) U.S. Cl. CPC G01R 15/18; G01R 19/155

(57) ABSTRACT

An inductive voltage tester comprises a voltage tester body (100), a display window (110) disposed on the voltage tester body (100), a signal acquisition module (210), a microcontroller (220) and a display module (230) disposed in the voltage tester body (100). The signal acquisition module (210) is configured to acquire a voltage signal of an object to be tested. The display module (230) comprises a display unit (231) and a drive unit (233) configured to drive the display unit. The microcontroller (220) is coupled to the display module (230) and the signal acquisition module (210), respectively, to receive the voltage signal acquired by the signal acquisition module (210). The microcontroller (220) is further configured to control the drive unit (233) according to the voltage signal to enable the display module to display a mark indicating a working status or a non-working status in the display window (110).

### FIELD OF THE INVENTION

The present disclosure relates to the technique filed of electronic tool, and particularly relates to an inductive voltage tester and a method of using the same.

### BACKGROUND OF THE INVENTION

The electroprobe also called the voltage tester is an electronic tool for testing whether the wire is energized or not. At present, there are various voltage testers in the market, in which the Non-contact voltage tester (Non-contact voltage, NCV) also call the inductive voltage tester is a widely used alternating current (AC) test tool. The sensitivity of the NCV tester is higher than that of the ordinary voltage tester, and the NCV tester can measure whether the wire to be tested is energized or not in air (non-contact). Meanwhile, the NCV tester can also provide an acousto-optical alerting function and is easy to use.

For the conventional inductive voltage tester, when the signal acquisition circuit in the inductive voltage tester fails to work, the electrical signal cannot be acquired, the inductive voltage tester can be still turned on normally, which in turn causes that when the AC within the valid measure range is tested, the inductive voltage tester cannot effectively determine whether the object to be tested is live or not, which results in misjudgment of the user and generates potential safety hazard for the user at the same time.

### SUMMARY OF THE INVENTION

On the basis of this, it is necessary to provide an inductive voltage tester and a method of using the same which can prevent misjudgment and provide a higher safety.

An inductive voltage tester includes: a voltage tester body; a display window disposed on the voltage tester body; a signal acquisition module disposed in the voltage tester body and configured to acquire a voltage signal of an object to be tested: a display module disposed in the voltage tester body, and the display module comprises a display unit and a drive unit configured to drive the display unit; and a microcontroller disposed in the voltage tester body; the microcontroller is coupled to the display module and the signal acquisition module, respectively, to receive the voltage signal acquired by the signal acquisition module; the microcontroller is further configured to control the drive unit according to the voltage signal to enable the display module to display a mark indicating a working status or a non-working status in the display window; wherein the mark indicating the non-working status is visible when the inductive voltage tester is switched on.

A method of using an inductive voltage tester includes the steps of: acquiring, by a signal acquisition module, a voltage signal of an object to be tested; receiving, by a microcontroller, the voltage signal acquired by the signal acquisition module and determining whether the voltage signal is normal or not; controlling, by the microcontroller, a drive unit to enable the display module to display a mark indicating a working status when the voltage signal is determined to be normal; or else controlling, by the microcontroller, the drive unit to enable the display module to display a mark indicating a non-working status.

When the above voltage tester is turned off or on standby, the display window thereof will show the mark indicating the non-working status. After the inductive voltage tester is turned on, the inductive voltage tester performs a detection to a known AC energized object. At this time, the signal acquisition module of the inductive voltage tester performs self-detection, and determines whether the signal acquisition module is normal or not. If the signal acquisition module is normal, then the microcontroller transmits the control instruction to the drive unit and then controls the drive unit to drive the display unit for displaying the mark indicating the working status. In other words, the inductive voltage tester can work normally. If the signal acquisition module fails to work, then the microcontroller transmits the control instruction to the drive unit and then controls the drive unit to drive the display unit for displaying the mark indicating the non-working status. In other words, the inductive voltage tester does not work normally, and cannot perform the alternating voltage detection for other energized objects to be tested. Therefore, the inductive voltage tester can effectively determine whether the energized object to be tested is live or not, which avoids the case of misjudgment and improves safety. It is more convenient to use the inductive voltage tester.

### BRIEF DESCRIPTION OF THE DRAWINGS

To illustrate the technical solutions according to the embodiments of the present disclosure or in the prior art more clearly, the accompanying drawings for describing the embodiments or the prior art are introduced briefly in the following. Apparently, the accompanying drawings in the following description are only some embodiments of the present disclosure, and persons of ordinary skill in the art can derive other drawings from the accompanying drawings without creative efforts.

FIG. 1 is a schematic diagram of an inductive voltage tester according to an embodiment;

FIG. 2 is a schematic diagram of another status of the inductive voltage tester shown in FIG. 1;

FIG. 3 is an inner block diagram of the inductive voltage tester shown in FIG. 1;

FIG. 4 is an inner circuit principle diagram of the inductive voltage tester shown in FIG. 1;

FIGS. 5(a) and 5(b) are schematic diagrams of a display module according to an embodiment;

FIGS. 6(a) and 6(b) are schematic diagrams of a display module according to another embodiment;

FIGS. 7(a) and 7(b) are schematic diagrams of a display module according to yet another embodiment;

FIG. 8 is a flow chart of a method of using the inductive voltage tester according to an embodiment.

### DETAILED DESCRIPTION OF THE EMBODIMENTS

Embodiments of the disclosure are described more fully hereinafter with reference to the accompanying drawings. The various embodiments of the disclosure may, however, be embodied in many different forms and should not be construed as limited to the embodiments set forth herein. Rather, these embodiments are provided so that this disclosure will be thorough and complete, and will fully convey the scope of the disclosure to those skilled in the art.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items.

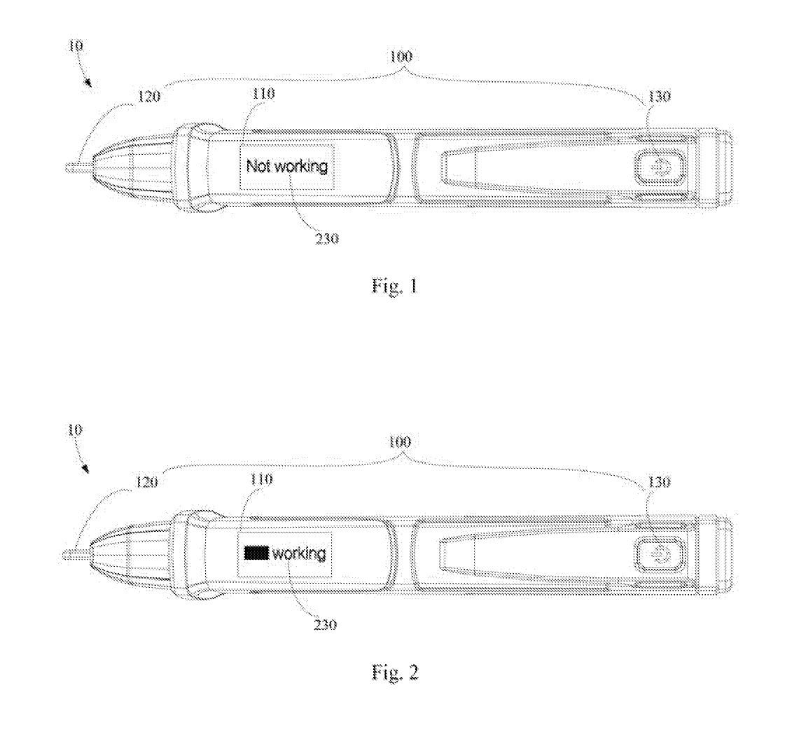

The description of the present disclosure is now described in detail with reference to the drawings. FIG. 1 and FIG. 2 are schematic diagrams of two different display statuses of the inductive voltage tester, respectively, in which the inductive voltage tester includes a voltage tester body 100; a display window 110 disposed on the voltage tester body 100; an inductive probe 120 and a switching button 130 disposed at the two ends of the voltage tester body 100, respectively.

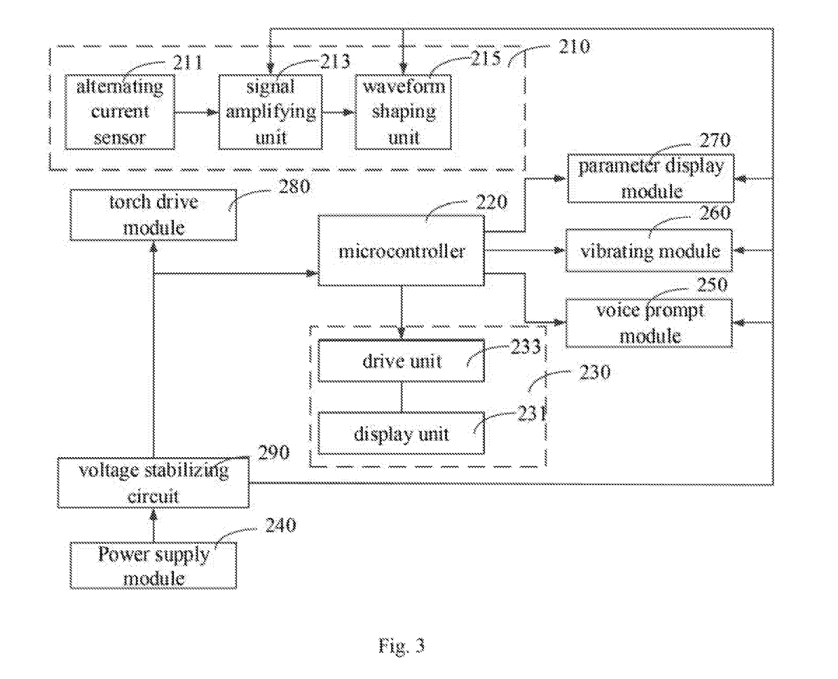

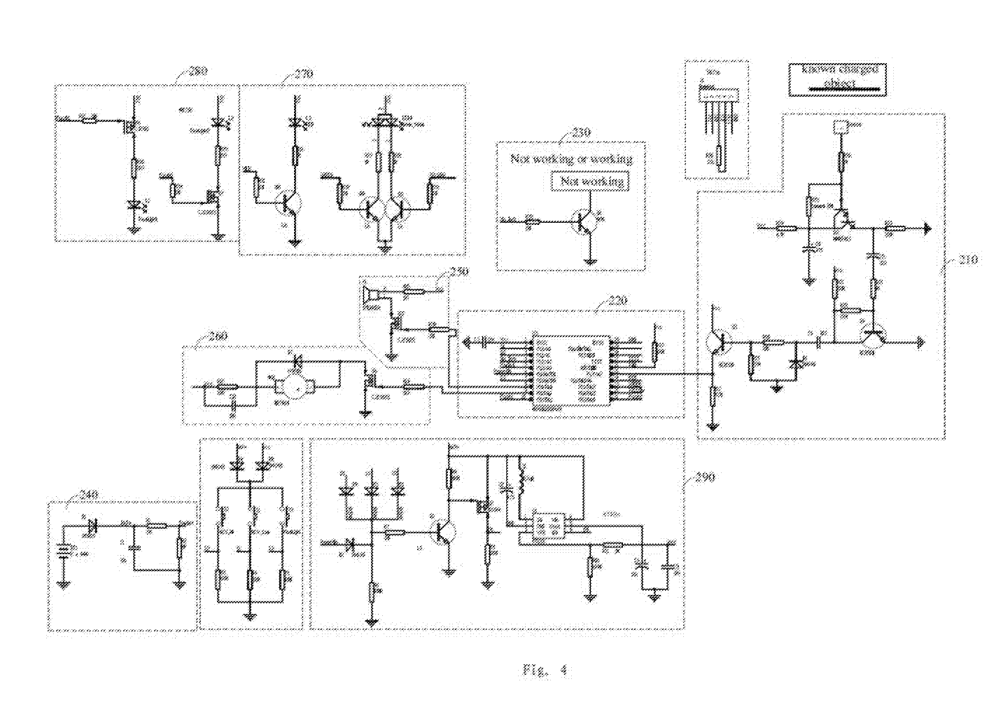

Referring FIG. 3 and FIG. 4, the inductive voltage tester 10 includes a signal acquisition module 210, a microcontroller 220, and a display module 230, which are located inside the inductive voltage tester 10.

The signal acquisition module 210 is configured to acquire a voltage signal of an object to be tested. The display module 230 includes a display unit 231 and a drive unit 233. The drive unit 233 is configured to control the display unit 231 to display a mark indicating a working status or a non-working status.

The microcontroller 220 is coupled to the signal acquisition module 210 and the display module 230 respectively to receive the voltage signal acquired by the signal acquisition module 210. The microcontroller 220 is further configured to control the drive unit 233 according to the voltage signal to enable the display unit 231 to display a mark indicating the working status or the non-working status. The mark indicating lire non-working status is visible on power-up (or by default). The mark can be made of photoluminescence material (phosphor), or the mark in the display unit 231 can be made of mediums of other characteristics.

The display unit 231 includes a first mark and a second mark both disposed in a region of the display window 110. The non-working status is indicated by a simultaneous appearance of the first mark and the second mark, and the working status is indicated by an individual appearance of the second mark. In the embodiment, the first mark and the second mark are made of phosphor.

Before the inductive voltage tester 10 is used, i.e., the inductive voltage tester is turned off or on standby; the region of its display window displays the first mark and the second mark indicating the non-working status. When the switching button 130 is pressed, the inductive voltage tester 10 is turned on. The inductive voltage tester 10 firstly detects a known AC energized object. At this time, the signal acquisition module 210 of the inductive voltage tester will perform self-detection, and determine whether the signal acquisition module 210 is normal or not. If the signal acquisition module 210 is normal, then the microcontroller 220 transmits the control instruction to the drive unit 233 and then controls the drive unit 233 of the display of the first mark. In other words, the drive unit 233 is controlled to shield the first mark, i.e., only the second mark indicating the working status is displayed, which indicates the inductive voltage tester can work normally. Therefore, the inductive voltage tester can perform detection for other energized objects to be tested. If the signal acquisition module 210 fails to work, i.e., the signal acquisition module 210 cannot acquire the voltage signal normally, then the microcontroller 220 transmits the control instruction to the drive unit 233 and controls the drive unit 233 to indicate the working status by displaying the first mark and the second mark simultaneously, which indicates the inductive voltage tester 10 docs not work normally, and cannot perform the alternating voltage detection for other energized objects to be tested.

In the embodiment, both the first mark and the second mark are characters. In other embodiments, the first mark and the second mark can also be dot, line or complex pattern as long as the working status and the non-working status can be identified.

In the embodiment, the character of the first mark is a prefix character, and the character of the second mark is a suffix character. Combination of the prefix character and the suffix character means the non-working status, and the suffix character individually means the working status.

The first mark in the display unit 231 is “not (Not, NOT)”, “no (No, NOT)” or other characters of negative meaning. Of course, various manners in English, in Chinese or in other languages can be used to indicate the first mark. The second mark indicating the working status in the display unit 231 is “working (Working)” or other characters indicating the working status. Various manners in English, in Chinese or in other languages can be used to indicate the second mark. In the embodiment, the first mark is “Not”, and the second mark is “working”.

In other words, during the usage of the inductive voltage tester, the inductive voltage tester detects the known AC energized objects. At the same time, the signal acquisition module 210 of the inductive voltage tester will perform self-detection. The microcontroller 220 controls the display unit 231 of the display module 230 to display and determine whether the inductive voltage tester can work normally or not. If the inductive voltage tester is in normal working status, then “working” is displayed as referred to FIG. 1. If the inductive voltage tester cannot work normally, then “Not working” is displayed as referred to FIG. 2. By self-detection of the signal acquisition module 210 and the display by the display module 230, it is safer and more convenient to use the inductive voltage tester.

Referring to FIG. 3 and FIG. 4, the signal acquisition module 210 includes an AC sensor 211, a signal amplifying unit 213, and a waveform shaping unit 215. The AC sensor 211, the signal amplifying unit 213, and the waveform shaping unit 215 are sequentially electrically coupled. The waveform shaping unit 215 is coupled to the microcontroller 220. The microcontroller 220 is configured to receive the voltage signal acquired by the AC sensor 211. In an embodiment, the AC sensor 211 is the inductive probe 120 shown in FIG. 1. The AC sensor 211 is an alternating voltage inductive sensor configured to acquire the voltage signal of AC. The inductive probe 120 can also be an AC inductive sensor configured to acquire the current signal of AC. The AC sensor 211 is configured to acquire the electrical signal of the energized object, and the acquired electrical signal is amplified by the signal amplifying unit 213 and then transmitted to the waveform shaping unit 215. The waveform of the amplified electrical signal is shaped by the waveform shaping unit 215 and then transmitted to the microcontroller 220. If the microcontroller 220 can receive the electrical signal from the signal acquisition module 210, it indicates that the signal acquisition module 210 completes the self-detection, and the inductive voltage tester can work normally; and vice versa.

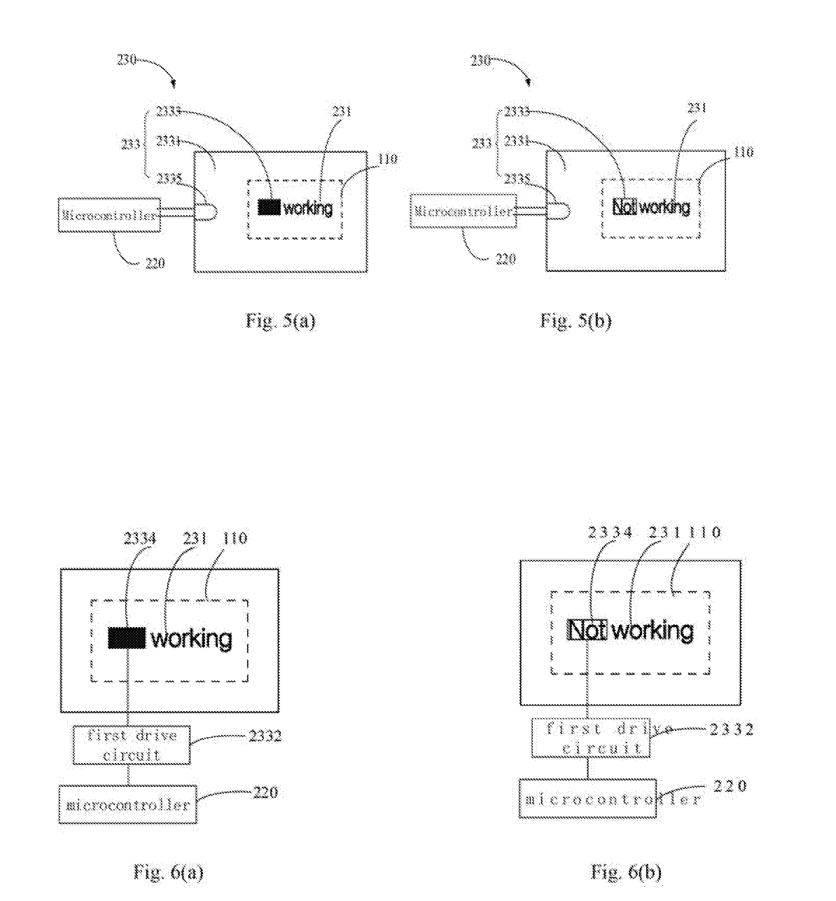

FIGS. 5(a) and 5(b) are schematic diagrams of the display module according to an embodiment. The display module 230 includes a display unit 231 and a drive unit 233. The drive unit 233 includes a light guiding plate 2331, a dielectric film 2333 disposed on a top surface of the light guiding plate, and a preset light source 2335 electrically coupled to the light guiding plate 2331. The light guiding plate 2331 is also called polymethyl methacrylate (PMMA), and is current the best macromolecule transparent material, the visible light transmittance of which can be up to 92% and is higher than the transmittance of glass.

The display unit 231 is located below the light guiding plate 2331, and the dielectric film 2333 covers the first mark “Not” of the display unit 231. The preset light source 2335 is coupled to the microcontroller 220, and the microcontroller 220 controls switching on and off of the preset light source 2335 by a PNP type triode. The preset light source 2335 is an ultraviolet LED lamp disposed on a side of the light guiding plate 2331. Generally, the ordinary glass can just transmit 0.6% of ultraviolet rays, but PMMA can transmit 73% of ultraviolet rays, i.e., the ultraviolet light can pass through PMMA. The part of the PMMA surface corresponding to the first mark “Not” is coated to form the dielectric film 2333, and the dielectric film 2333 can enhance the filter function for the ultraviolet light. The ultraviolet light can be absorbed, and transmission of the ultraviolet light can be prevented. Further, the ultraviolet LED lamp can also be disposed below the light guiding plate 2331, and the position of the ultraviolet LED lamp can be correspondingly adjusted according to requirement.

Before the inductive voltage tester is turned on and then used, the region of the display window 110 of the inductive voltage tester shows the character “Not working”. After the inductive voltage tester is turned on, the known energized object will be tested. If the signal acquisition module 210 is normal, then the microcontroller 220 transmits the control instruction to control the ultraviolet LED lamp to be turned on. The ultraviolet light radiates the light guiding plate 2331, thus activating the respective dielectric film 2333 covering the first mark “Not” on the light guiding plate 2331. The ultraviolet light is absorbed by the dielectric film 2333 and cannot pass through the light guiding plate 2331. In other words, the first mark “Not” is shielded, as referred to FIG. 4(a). Only the second mark “working” is displayed in the display window 110, which indicates the inductive voltage tester can work normally. If the signal acquisition module 210 fails to work, the electrical signal cannot be acquired normally, and then the microcontroller 220 transmits the control instruction to control the ultraviolet LED lamp not to be turned on. Referring to FIG. 4(b), the character “Not working” is displayed in the display window, which indicates the inductive voltage tester cannot work normally.

FIGS. 6(a) and 6(b) are schematic diagrams of the display module according to another embodiment. The drive unit 233 in the display module 230 includes a first drive circuit 2332 and a display screen 2334 electrically coupled to the first drive circuit 2332, in which the display screen 2334 covers the first mark of the display unit 231; the microcontroller 220 is coupled to the first drive circuit 2332 and configured to control the first drive circuit 2332 to drive the display screen 2334 for display. The display screen is an LCD or LED display screen. In the embodiment, the display screen is an LCD screen, and the first drive circuit 2332 is an LCD drive circuit.

Before the inductive voltage tester is turned on and used, the display window 110 of the inductive voltage tester shows the character “Not working”. After the inductive voltage tester is turned on, the known energized object will be tested. If the signal acquisition module 210 is normal, then the microcontroller 220 transmits the control instruction to control the first drive circuit 2332 to drive the LCD screen 2334 to display. After the LCD screen 2334 displays the pattern, the first mark “Not” in the display window is shielded. Referring to FIG. 5(a), only the second mark “working” is displayed in the display window 110, which indicate the inductive voltage tester can work normally. If the signal acquisition module 210 fails to work, the electrical signal cannot be acquired normally, then the microcontroller 220 transmits the control instruction to control the LCD screen not to display. Referring to FIG. 5(b), the character “Not working” is displayed in the display window, which indicates the inductive voltage tester cannot work normally.

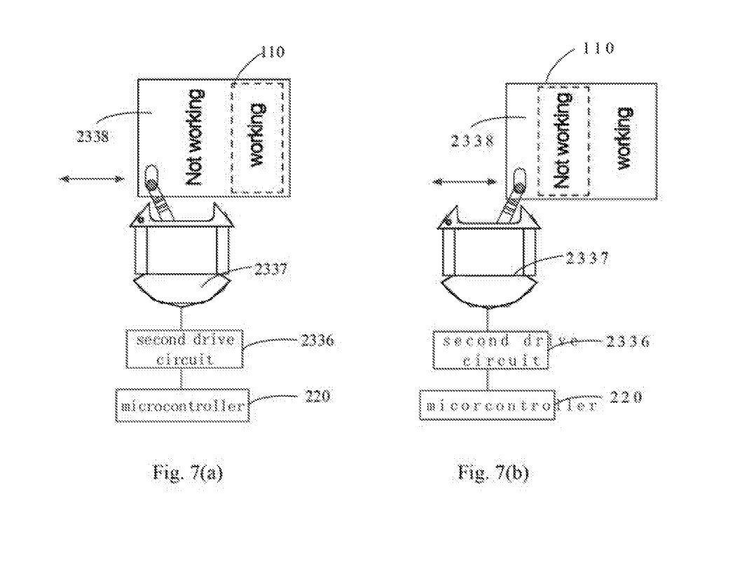

FIGS. 7(a) and 7(b) are schematic diagrams of the display module according to yet another embodiment. The drive unit 233 in the display module 230 includes a second drive circuit 2336, an electromagnetic valve 2337, a sliding block 2338 and a linear sliding rail (not shown). The electromagnetic valve 2337 is coupled to the second drive circuit 2336 and the sliding block 2338, respectively. The sliding block 2338 is located on the linear sliding rail. The second drive circuit 2336 is coupled to the microcontroller 220. The microcontroller 220 controls the second drive circuit 2336 to drive the electromagnetic valve 2337 for bringing the sliding block 2338 to move along the linear sliding rail (i.e. along the direction of the arrow in FIGS. 7(a) and 7(b)).

The number of the first mark in the display unit 231 is one; the number of the second marks is two; both the first mark and the second marks are disposed on the sliding block 2338, and the first mark and one of the second marks are arranged in a row, i.e. “Not working”; the other one of the second marks “working” is parallel to the one of the second marks, i.e. “Not working” and “working” are disposed in parallel, and the other one of the two second marks is perpendicular to the linear sliding rail (the movement direction of the sliding block 2338).

The display window is disposed corresponding to the first mark and the one of the second marks arranged in the row (i.e. “Not working”), or the display window 110 is disposed corresponding to the other one of the second marks “working”.

Before the inductive voltage tester is turned on and used, the display window 110 of the inductive voltage tester shows the character “Not working”. After the inductive voltage tester is turned on, the known energized object will be tested. If the signal acquisition module 210 is normal, then the microcontroller 220 transmits the control instruction to control the second drive circuit 2336 to drive the electromagnetic valve 2337 for bringing the sliding block 2338 to move along the linear sliding rail (i.e. along the right direction of the arrow in FIGS. 7(a) and 7(b)). Referring to FIG. 6(a), the other one of the second marks in the display window 110 is “working”, which indicates the inductive voltage tester can work normally. If the signal acquisition module 210 fails to work, then the microcontroller 220 transmits the control instruction to control the second drive circuit 2336 to drive the electromagnetic valve 2337 for bringing the sliding block 2338 to move along the linear sliding rail (i.e. along the left direction of the arrow in FIGS. 7(a) and 7(b)). Referring to FIG. 6(b), the display window 100 shows the first mark and the one of the second marks, i.e. “Not working”, which indicates the inductive voltage tester cannot work normally.

In the embodiment, the inductive voltage tester further includes a voice prompt module 250 coupled to the microcontroller 220; the microcontroller 220 is further configured to control the voice prompt module 250 according to the voltage signal, thus enabling the voice prompt module 250 to issue a prompt tone indicating the working status or the non-working status. If the signal acquisition module 210 is normal, then the prompt tone “working”, or a short beep is issued. If the signal acquisition module 210 fails to work, then the prompt tone “Not working”, or a long beep is issued. The content of the prompt tone can be set according to actual requirement.

In the embodiment, the inductive voltage tester further includes a vibrating module 260 coupled to the microcontroller 220. If the inductive voltage tester cannot acquire the voltage signal, then the vibrating module 260 begins to vibrate to indicate the user.

Referring to FIG. 3 and FIG. 4, in the embodiment, the inductive voltage tester further includes a power supply module 240 configured to power the inductive voltage tester 10, a parameter display module 270 configured to display a test parameter, a torch drive module 280 configured to illuminate, and a voltage stabilizing circuit 290 configured to process the acquired electrical signal. The parameter display module 270, the torch drive module 280 and the voltage stabilizing circuit 290 are coupled to the microcontroller 220, and the microcontroller 220 controls them to work, respectively.

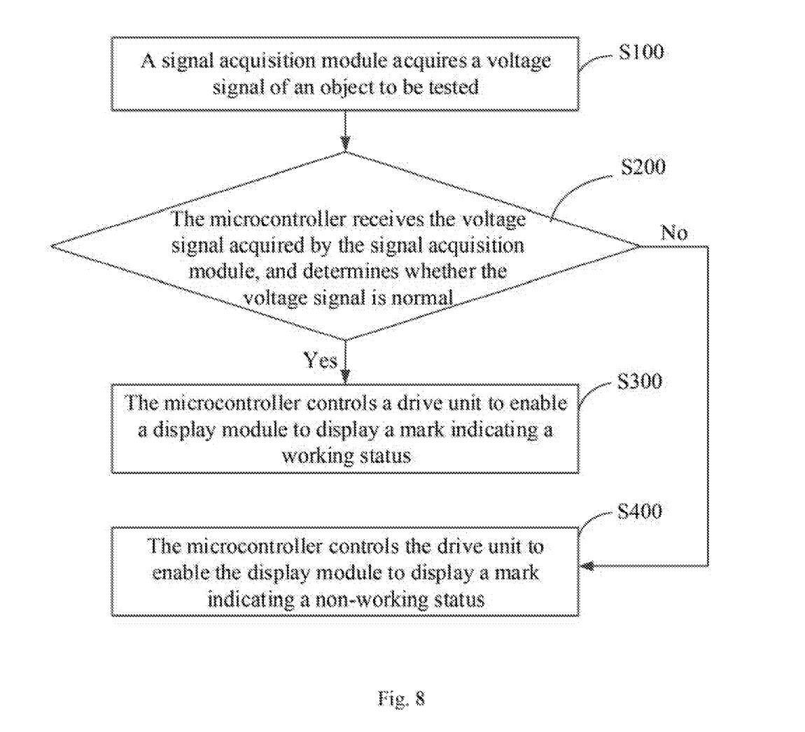

Further, FIG. 8 is a flow chart of a method of using the inductive voltage tester according to an embodiment. The method includes the steps of;

In step S100: a signal acquisition module acquires a voltage signal of an object to be tested.

An AC sensor in the signal acquisition module acquires an electrical signal of the known energized object, and the acquired electrical signal is amplified by a signal amplifying unit and then transmitted to a waveform shaping unit. The amplified electrical signal is shaped by the waveform shaping unit and then transmitted to a microcontroller.

In step S200; the microcontroller receives the voltage signal acquired by the signal acquisition module, and determines whether the voltage signal is normal or not.

The microcontroller receives the voltage signal acquired by the signal acquisition module, and determines whether the voltage signal is normal according to voltage signal parameters of the known energized object. Generally, if the voltage signal received by the microcontroller is conform to the voltage signal of the known energized object, then the voltage signal received is considered to be normal; or else, the voltage signal received is considered to be not normal.

In step S300: when the voltage signal is determined to be normal, the microcontroller controls a drive unit to enable a display module to display a mark indicating a working status.

A first mark in the display unit is “not (Not, NOT)”, “no (No, NOT)” or other character indicating negative meaning. Of course, various manners in English, in Chinese or in other languages can be used to indicate the first mark. A second mark indicating the working status in the display unit is “working (Working)” or other characters indicating the working status. Various manners in English, in Chinese or in other languages can be used to indicate the second mark. In the embodiment, the first mark is “Not”, and the second mark is “working”.

When the voltage signal is determined to be normal, the microcontroller 220 transmits the control instruction to control the drive unit 233 to drive a display of the first mark, the drive unit 233 is controlled to shield the first mark, and only the second mark indicating the working status “working” is displayed. In other words, the inductive voltage tester can work normally, and other energized objects to be tested can be tested.

In step S400: When the voltage signal is determined to be not normal, the microcontroller controls the drive unit to enable the display module to display a mark indicating a non-working status.

If the signal acquisition module 210 fails to work, i.e., the voltage signal cannot be acquired normally, or the acquired voltage signal deviates far from the normal voltage signal, then the drive unit is controlled to indicate the non-working status by displaying the first mark and the second mark simultaneously, i.e. “Not working”. In other words, the inductive voltage tester does not work normally, and cannot perform alternating voltage detection for other energized objects to be tested.

Although the disclosure is illustrated and described herein with reference to specific embodiments, the disclosure is not intended to be limited to the details shown. Rather, various modifications may be made in the details within the scope and range of equivalents of the claims and without departing from the disclosure. Therefore, the scope of the present disclosure shall be defined by the appended claims.

What is claimed is:

1. An inductive voltage tester, comprising:
a voltage tester body;
a display window disposed on the voltage tester body;
a signal acquisition module disposed in the voltage tester body and configured to acquire a voltage signal of an object to be tested;
a display module disposed in the voltage tester body, wherein the display module comprises a display unit and a drive unit configured to drive the display unit; and
a microcontroller disposed in the voltage tester body, wherein the microcontroller is coupled to the display module and the signal acquisition module, respectively, to receive the voltage signal acquired by the signal acquisition module; the microcontroller is further configured to control the drive unit according to the voltage signal to enable the display module to display a mark indicating a working status or a non-working status in the display window;
wherein the mark indicating the non-working status is visible when the inductive voltage tester is switched on.

2. The inductive voltage tester of claim 1. wherein the display unit comprises a first mark and a second mark both disposed in a region of the display window, the non-working status is indicated by a simultaneous appearance of the first mark and the second mark, and the working status is indicated by an individual appearance of the second mark.

3. The inductive voltage tester of claim 1, wherein the drive unit comprises:
a light guiding plate, the display unit being located below the light guiding plate;
a preset light source electrically coupled to the light guiding plate and coupled to the microcontroller; and
a dielectric film disposed on a top surface of the light guiding plate;
wherein the dielectric film is configured to absorb the preset light source and shield the first mark;
wherein the microcontroller is configured to control switching on and off of the preset light source.

4. The inductive voltage tester of claim 3, wherein the preset light source is an ultraviolet LED lamp disposed a side of the light guiding plate.

5. The inductive voltage tester of claim 2, wherein the drive unit comprises a first drive circuit and a display screen electrically coupled to the first drive circuit; wherein the display screen covers the first mark of the display unit; and wherein the microcontroller is coupled to the first drive circuit and configured to control the first drive circuit to drive the display screen for display.

6. The inductive voltage tester of claim 5, wherein the display screen is an LCD or LED display screen.

7. The inductive voltage tester of claim 2, wherein the drive unit comprises;
a linear sliding rail;
a sliding block located on the linear sliding rail;
a second drive circuit coupled to the microcontroller; and
an electromagnetic valve coupled to the second drive circuit and the sliding block, respectively;
wherein the microcontroller is configured to control the second drive circuit to drive the electromagnetic valve to enable the sliding block to move along the linear sliding rail;
wherein the number of the first mark in the display unit is one;
wherein the number of the second marks is two;
wherein both the first mark and the two second marks are disposed on the sliding block, and the first mark and one of the two second marks are arranged in a row;
wherein the other one of the two second marks is parallel with the one of the two second marks, and the other one of the two second marks is perpendicular to the linear sliding rail; and
wherein the display window is disposed corresponding to the first mark and the one of the second marks arranged in the row or corresponding to the other one of the second marks.

8. The inductive voltage tester of claim 2, wherein both the first mark and the second mark are characters.

9. The inductive voltage tester of claim 1, wherein the signal acquisition module comprises an alternating current (AC) sensor, a signal amplifying unit, and a waveform shaping unit; wherein the AC sensor, the signal amplifying unit, and the waveform shaping unit are sequentially electrically coupled; wherein the waveform shaping unit is coupled to the microcontroller; and wherein the microcontroller is configured to receive the voltage signal acquired by the AC sensor.

10. The inductive voltage tester of claim 1, further comprising a voice prompt module coupled to the microcontroller; wherein the microcontroller is further configured to control the voice prompt module according to the voltage signal, thus enabling the voice prompt module to issue a prompt tone indicating the working status or the non-working status.

11. A method of using an inductive voltage tester, comprising the steps of:
acquiring, by a signal acquisition module, a voltage signal of an object to be tested;
receiving, by a microcontroller, the voltage signal acquired by the signal acquisition module and determining whether the voltage signal is normal or not;
controlling, by the microcontroller, a drive unit to enable the display module to display a mark indicating a working status when the voltage signal is determined to be normal; or else
controlling, by the microcontroller, the drive unit to enable the display module to display a mark indicating a non-working status.
